(19) United States
(12) Patent Application Publication
(10) Pub. No.: US 2009/0283133 A1
(43) Pub. Date: Nov. 19, 2009

(54) SOLAR CONCENTRATING MIRROR

(75) Inventors: Timothy J. Hebrink, Scandia, MN (US); Tracy L. Anderson, Hudson, WI (US); Susannah C. Clear, Hastings, MN (US); Andrew K. Hartzell, Hudson, WI (US); Stephen A. Johnson, Woodbury, MN (US); Edward J. Kivel, Stillwater, MN (US); Michael F. Weber, Shoerview, MN (US); Ta-Hua Yu, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/120,258

(22) Filed: May 14, 2008

(51) Int. Cl. H01L 31/042

(52) U.S. Cl. 136/246

(57) ABSTRACT

An article that is suitable for use as a solar concentrating mirror for enhancing the use of solar collection devices, such as solar cells. The article includes a multilayer optical film and a compliant UV protective layer. The article addresses degradation issues in solar concentration devices, provides specific bandwidths of electromagnetic energy to the solar cell while eliminating or reducing undesirable bandwidths of electromagnetic energy that may degrade or adversely affect the solar cell, and renders a compliant sheet of material that may be readily formed into a multitude of shapes or constructions for end use applications.

### TECHNICAL FIELD

This invention relates to wavelength selective mirrors suitable for application as solar concentrators for improving the efficiency and operation of solar cells.

### BACKGROUND

Conventional solar concentrating mirrors are typically used to direct broad bandwidths of solar energy onto a solar cell or solar heat transfer element. However, electromagnetic radiation of certain wavelengths reflected from the solar concentrating mirror onto the solar element may adversely affect the solar element. For example, wavelengths in the infrared spectrum can cause certain solar cells to undesirably increase in temperature. As a result, the solar cells may lose efficiency, and overtime, degrade due the excessive thermal exposure. Long term exposure to ultraviolet (“UV”) light is one example that often leads to premature degradation of components of the solar cell.

The materials employed in the construction of solar concentrating mirrors may comprise compositions that are adversely affected by specific bandwidths of electromagnetic radiation. Degradation of those materials will cause a drop in concentrating efficiency and potentially the complete failure of the solar concentrating mirror. Long term exposure to UV light is one example that often leads to premature degradation of materials exposed to sunlight.

### SUMMARY

The present invention is directed to an article that is suitable for use as a solar concentrating mirror for enhancing the use of solar collection devices, such as solar cells. The article is a unique combination of layered compositions that: (i) address degradation issues in solar concentration devices, (ii) provide specific bandwidths of electromagnetic energy to the solar cell while eliminating or reducing undesirable bandwidths of electromagnetic energy that may degrade or adversely affect the efficacy of the solar cell, and (iii) render a compliant sheet of material that may be readily formed into a multitude of shapes or constructions for end use applications.

The article comprises a multilayer optical film and a compliant UV protective layer. The multilayer optical film has an optical stack that includes a plurality of alternating layers, the alternating layers having at least one birefringent polymer layer and at least one second polymer layer.

The compliant UV protective layer is applied onto a surface of the multilayer optical film to create an article that may be used as a solar concentrating mirror for concentrating a specific bandwidth of light onto a solar cell. For purposes of the invention, light is intended to mean solar irradiance. The resulting article reflects at least a major portion of the average light across the range of wavelengths that corresponds with the absorption bandwidth of a selected solar cell and either transmits or absorbs a major portion of light outside the absorption bandwidth of the selected solar cell.

The article is a compliant sheet of material that may be readily formed into various shapes or constructions. For example, the article may be thermoformed into troughs, parabolic shapes, etc. In one embodiment, the article may be formed around the solar cell in order to focus electromagnetic energy onto more than one surface of the solar cell.

The solar cells suitable for use with the novel solar concentrating mirror include both silicon based and non-silicon based materials. The constructions may include single junction cells and multi-junction cells. In application and use, the article and solar cell combinations may be placed into arrays and further incorporated into celestial tracking mechanisms.

### BRIEF DESCRIPTION OF DRAWINGS

FIG. 1 is a schematic cross sectional view of the article of the present invention with an optional durable top coat layer depicted in phantom;

FIG. 2 is a schematic view of a solar cell and one embodiment of an article of the present invention;

FIG. 3 is a schematic view of another embodiment of the present invention in combination with a solar cell;

FIGS. 4a, 4b, and 4c are graphical representations of the solar irradiation and absorption spectrum of various solar cells and the operating window created by the concentrating mirror of the present invention;

FIG. 5a is a schematic overhead view of an array of solar cells with multiple articles of the present invention;

FIG. 5b is a schematic cross sectional view of the embodiment of FIG. 5a with optional protective layers in phantom;

FIG. 5c is schematic cross sectional view of FIG. 5a depicting an alternative embodiment of a thermoformed article around multiple solar cells; and

FIG. 6 is a schematic cross sectional view depicting a thermoformed article of an array of multiple solar concentrating mirrors.

### DETAILED DESCRIPTION

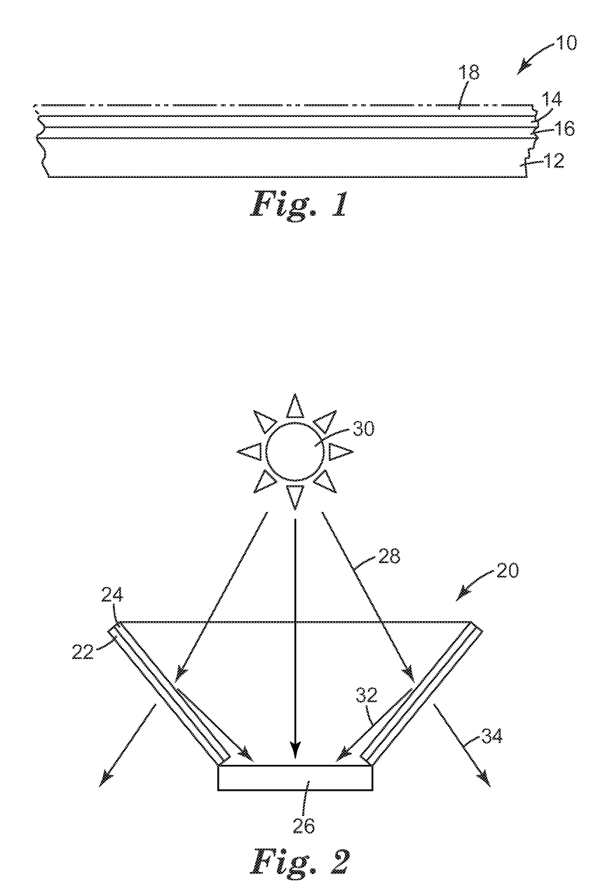

FIG. 1 depicts the article 10 of the present invention. The article 10 comprises a multilayer optical film 12 and a compliant UV protective layer 14 that in application serves as a solar concentrating mirror. The multilayer optical film has an optical stack that includes a plurality of alternating layers (not shown). The alternating layers of the multilayer optical film 12 include at least one birefringent polymer layer and at least one second polymer layer.

The compliant UV protective layer 14 is applied onto a surface of the multilayer optical film 12 to create the article 10 that may be used as a solar concentrating mirror for concentrating light onto a solar cell (not shown). The resulting article 10 reflects at least a major portion of the average light across the range of wavelengths that corresponds with the absorption bandwidth of a selected solar cell and either transmits or absorbs a major portion of light outside the absorption bandwidth of the selected solar cell. Optional tie layer 16 and durable top coat 18 may also be employed in an alternative embodiment of article 10.

The UV protective layer 14, and therefore article 10, is generally a compliant sheet of material. For purposes of the present invention, the term compliant is an indication that article 10 is dimensionally stable yet possesses a pliable characteristic that enables subsequent molding or shaping into various forms. Preferably, the compliant film has less than 10% film formers in the UV protective layer 14. According to the present description, film formers may be crosslinking agents or other multifunctional monomers. In a most preferred embodiment, article 10 may be thermoformed into various shapes or structures for specific end use applications.

FIG. 2 illustrates a general application of the article 20 as a solar concentrating mirror. Article 20 comprises a multilayer optical film 22 and a UV protective layer 24 positioned in close proximity to a solar cell 26. The article 20 receives electromagnetic radiation 28 from the sun 30. A select bandwidth 32 of the electromagnetic radiation 28 is reflected onto solar cell 26. An undesirable bandwidth 34 of electromagnetic radiation passes through article 20 and is not reflected onto solar cell 26.

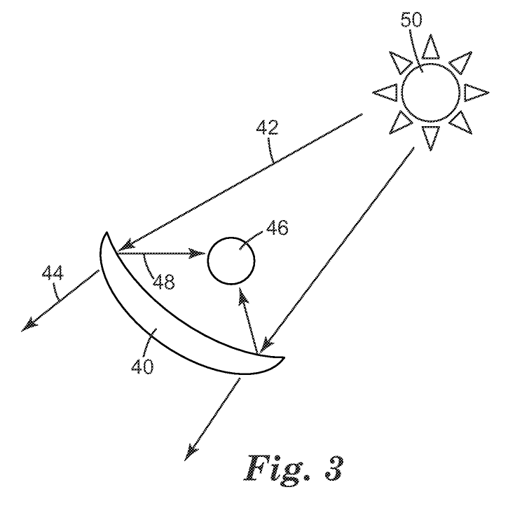

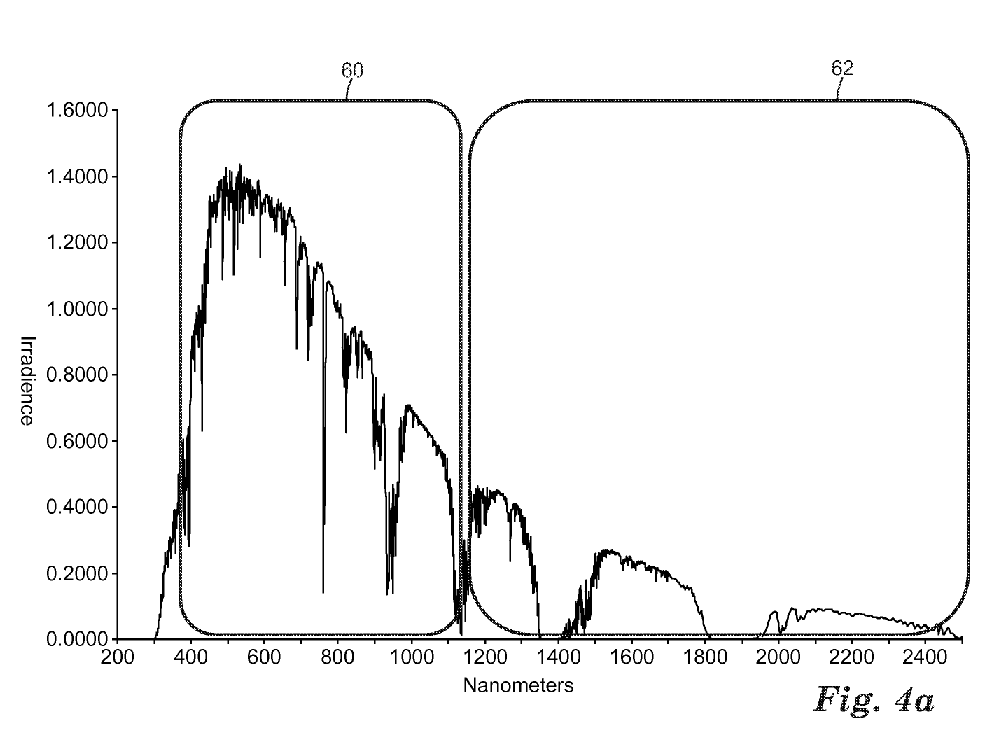

FIG. 3 is another general embodiment depicting the inventive article in the form of a parabolic solar concentrating mirror 40. Electromagnetic radiation 42 from the sun 50 is received by the parabolic solar concentrating mirror 40. A preferred bandwidth 48 is reflected onto a solar cell 46 while an undesirable bandwidth 44 of electromagnetic radiation passes through the parabolic solar concentrating mirror 40 and is not reflected onto the solar cell 46 where it could potentially alter the operational efficiency of the solar cell. The shape of the article may include parabolic or other curved shapes, such as for example sinusoidal.

### Multilayer Optical Films

Conventional multilayer optical films with alternating layers of at least one birefringent polymer and one second polymer may be employed in creating the article of the present invention. The multilayer optical films are generally a plurality of alternating polymeric layers selected to achieve the reflection of a specific bandwidth of electromagnetic radiation.

Materials suitable for making the at least one birefringent layer of the multilayer optical film of the present disclosure include polymers such as, for example, polyesters, copolyesters and modified copolyesters. In this context, the term “polymer” will be understood to include homopolymers and copolymers, as well as polymers or copolymers that may be formed in a miscible blend, for example, by co-extrusion or by reaction, including transesterification. The terms “polymer” and “copolymer” include both random and block copolymers. Polyesters suitable for use in some exemplary multilayer optical films constructed according to the present disclosure generally include carboxylate and glycol subunits and can be generated by reactions of carboxylate monomer molecules with glycol monomer molecules. Each carboxylate monomer molecule has two or more carboxylic acid or ester functional groups and each glycol monomer molecule has two or more hydroxy functional groups. The carboxylate monomer molecules may all be the same or there may be two or more different types of molecules. The same applies to the glycol monomer molecules. Also included within the term “polyester” are polycarbonates derived from the reaction of glycol monomer molecules with esters of carbonic acid.

Suitable carboxylate monomer molecules for use in forming the carboxylate subunits of the polyester layers include, for example, 2,6-naphthalene dicarboxylic acid and isomers thereof, terephthalic acid; isophthalic acid; phthalic acid; azelaic acid; adipic acid; sebacic acid; norbornene dicarboxylic acid; bi-cyclo-octane dicarboxylic acid; 1,4-cyclohexane dicarboxylic acid and isomers thereof, t-butyl isophthalic acid, trimellitic acid, sodium sulfonated isophthalic acid; 4,4′-biphenyl dicarboxylic acid and isomers thereof, and lower alkyl esters of these acids, such as methyl or ethyl esters. The term “lower alkyl” refers, in this context, to C1-C10 straight-chained or branched alkyl groups.

Suitable glycol monomer molecules for use in forming glycol subunits of the polyester layers include ethylene glycol; propylene glycol; 1,4-butanediol and isomers thereof, 1,6-hexanediol; neopentyl glycol; polyethylene glycol; diethylene glycol; tricyclodecanediol; 1,4-cyclohexanedimethanol and isomers thereof; norbornanediol; bicyclo-octanediol; trimethylol propane; pentaerythritol; 1,4-benzenedimethanol and isomers thereof, bisphenol A; 1,8-dihydroxy biphenyl and isomers thereof, and 1,3-bis(2-hydroxyethoxy)benzene.

An exemplary polymer useful as the birefringent layer in the multilayer optical films of the present invention is polyethylene naphthalate (PEN), which can be made, for example, by reaction of naphthalene dicarboxylic acid with ethylene glycol. Polyethylene 2,6-naphthalate (PEN) is frequently chosen as a birefringent polymer. PEN has a large positive stress optical coefficient, retains birefringence effectively after stretching, and has little or no absorbance within the visible range. PEN also has a large index of refraction in the isotropic state. Its refractive index for polarized incident light of 550 nm wavelength increases when the plane of polarization is parallel to the stretch direction from about 1.64 to as high as about 1.9. Increasing molecular orientation increases the birefringence of PEN. The molecular orientation may be increased by stretching the material to greater stretch ratios and holding other stretching conditions fixed. Copolymers of PEN, such as those described in U.S. Pat. No. 6,352,761 and U.S. Pat. No. 6,449,093 are particularly useful for their low temperature processing capability making them more coextrusion compatible with less thermally stable second polymers. Other semicrystalline polyesters suitable as birefringent polymers include, for example, polybutylene 2,6-naphthalate (PBN), polyethylene terephthalate (PET), and copolymers thereof such as those described in U.S. Pat. No. 6,449,093 B2 or U.S. Pat. App. No. 20060084780, both herein incorporated by reference in their entirety. Alternatively, syndiotactic polystyrene (sPS) is another useful birefringent polymer.

The second polymer of the multilayer optical film can be made from a variety of polymers having glass transition temperatures compatible with that of the first birefringent polymer and having a refractive index similar to the isotropic refractive index of the birefringent polymer. Examples of other polymers suitable for use in optical films and, particularly, in the second polymer include vinyl polymers and copolymers made from monomers such as vinyl naphthalenes, styrene, maleic anhydride, acrylates, and methacrylates. Examples of such polymers include polyacrylates, polymethacrylates, such as poly (methyl methacrylate) (PMMA), and isotactic or syndiotactic polystyrene. Other polymers include condensation polymers such as polysulfones, polyamides, polyurethanes, polyamic acids, and polyimides. In addition, the second polymer can be formed from homopolymers and copolymers of polyesters, polycarbonates, fluoropolymers, and polydimethylsiloxanes, and blends thereof.

Other exemplary suitable polymers, especially for use as the second polymer, include homopolymers of polymethylmethacrylate (PMMA), such as those available from Ineos Acrylics, Inc., Wilmington, Del., under the trade designations CP71 and CP80, or polyethyl methacrylate (PEMA), which has a lower glass transition temperature than PMMA. Additional second polymers include copolymers of PMMA (coPMMA), such as a coPMMA made from 75 wt % methylmethacrylate (MMA) monomers and 25 wt % ethyl acrylate (EA) monomers, (available from Ineos Acrylics, Inc., under the trade designation Perspex CP63), a coPMMA formed with MMA comonomer units and n-butyl methacrylate (nBMA) comonomer units, or a blend of PMMA and poly(vinylidene fluoride) (PVDF).

Yet other suitable polymers, especially useful as the second polymer, include polyolefin copolymers such as poly (ethylene-co-octene) (PE-PO) available from Dupont Performance Elastomers under the trade designation Engage 8200, poly (propylene-co-ethylene) (PPPE) available from Fina Oil and Chemical Co., Dallas, Tex., under the trade designation Z9470, and a copolymer of atactic polypropylene (aPP) and isotatctic polypropylene (iPP). The multilayer optical films can also include, for example in the second polymer layers, a functionalized polyolefin, such as linear low density polyethylene-g-maleic anhydride (LLDPE-g-MA) such as that available from E.I. duPont de Nemours & Co., Inc., Wilmington, Del., under the trade designation Bynel 4105.

Preferred polymer compositions suitable as the second polymer in alternating layers with the at least one birefringent polymer include PMMA, CoPMMA, polydimethyl siloxane oxamide based segmented copolymer (SPOX), fluoropolymers including homopolymers such as PVDF and copolymers such as those derived from tetrafluoroethylene, hexafluoropropylene, and vinylidene fluoride (THV), blends of PVDF/PMMA, acrylate copolymers, styrene, styrene copolymers, silicone copolymers, polycarbonate, polycarbonate copolymers, polycarbonate blends, PC/SMA blends, and cyclic-olefin copolymers.

The selection of the polymer compositions used in creating the multilayer optical film will depend upon the desired bandwidth that will be reflected onto a chosen solar cell. Higher refractive index differences between the birefringent polymer and the second polymer create more optical power thus enabling more reflective bandwidth. Alternatively, additional layers may be employed to provide more optical power. Preferred combinations of birefringent layers and second polymer layers may include, for example, the following: PET/THV, PET/SPOX, PEN/THV, PEN/SPOX, PEN/PMMA, PET/CoPMMA, PEN/CoPMMA, CoPEN/PMMA, CoPEN/SPOX, sPS/SPOX, sPS/THV, CoPEN/THV, PET/fluoroelastomers, sPS/fluoroelastomers and CoPEN/fluoroelastomers.

In one embodiment, two or more multi-layer optical mirror with different reflection bands are laminated together to broaden the reflection band. For example, a PEN/PMMA multi-layer reflective mirror which reflects 98% of the light from 400 nm to 900 nm would be laminated to a PEN/PMMA multi-layer reflective mirror which reflects 98% of the light from 900 nm to 1800 nm to create a broadband mirror reflecting light from 400 nm to 1800 nm.

The multilayer optical films are produced according to conventional processing techniques, such as those described in U.S. Pat. No. 6,783,349, herein incorporated by reference in its entirety. The multilayer optical films may also include non-optical protective boundary layers, such as for example those disclosed in U.S. Pat. No. 6,783,349.

### UV Protective Layer

A UV protective layer is applied onto a surface of the multilayer optical film and shields the multilayer optical film from UV radiation that may cause degradation. Solar light, in particular the ultraviolet radiation from 280 to 400 nm can induce degradation of plastics, which in turn results in color change and deterioration on mechanical properties. Inhibition of photo-oxidative degradation is important for outdoor applications wherein long term durability is mandatory. The absorption of UV light by polyethylene terephthalates, for example, starts at around 360 nm, increases markedly below 320 nm and is very pronounced at below 300 nm. For polyethylene naphthalates, it strongly absorbs UV light in the 310-370 nm range, with an absorption tail extending to about 410 nm, and with absorption maxima occurring at 352 nm and 337 nm. Chain cleavage occurs in the presence of oxygen, and the predominant photooxidation products are carbon monodioxide, carbon dioxide, and carboxylic acids. Besides the direct photolysis of the ester groups, consideration has to be given to oxidation reactions which likewise form carbon dioxide via peroxide radicals.

The UV protective layer may shield the multilayer optical film by reflecting UV light, absorbing UV light, scattering UV light, or a combination thereof. In general, the UV protective film may include any polymer composition that is capable of withstanding UV radiation for an extended period of time while either reflecting, scattering, or absorbing UV radiation. Non-limiting examples of such polymers include PMMA, silicone thermoplastics, fluoropolymers, and their copolymers, and blends thereof. An exemplary UV protective layer comprises PMMA/PVDF blends.

A variety of optional additives may be incorporated into the UV protective layer to assist in its function of protecting the multilayer optical film. Non-limiting examples of the additives include one or more compounds selected from ultra violet absorbers, hindered amine light stabilizers, anti-oxidants, and combinations thereof.

UV stabilizers such as UV absorbers are chemical compounds which can intervene in the physical and chemical processes of photo-induced degradation. The photooxidation of polymers from UV radiation can therefore be prevented by use of a protective layer containing UV absorbers to effectively block UV light. For the purpose of the present invention, UV stabilizers suitable as light stabilizers are red shifted UV absorbers (RUVA) which absorb at least 70%, preferably 80%, particularly preferably greater than 90% of the UV light in the wavelength region from 180 to 400 nm. The RUVA are suitable if they are highly soluble in polymers, highly absorptive, photo-permanent and thermally stable in the temperature range from 200 to 300° C. for extrusion process to form the protective layer. The UVA can also be highly suitable if they can be copolymerizable with monomers to form protective coating layer by UV curing, gamma ray curing, e-beam curing, or thermal curing processes.

The RUVA has enhanced spectral coverage in the long-wave UV region, enabling it to block the high wavelength UV light that can cause yellowing in polyesters. Typical protective layer thicknesses are from 0.5 to 15 mil comprising a RUVA loading level of 2-10%. One of the most effective RUVA is a benzotriazole compound, 5-trifluoromethyl-2-(2-hydroxy-3-alpha-cumyl-5-tert-octylphenyl)-2H-benzotriazole (CGL-0139). Other preferred benzotriazoles include 2-(2-hydroxy-3,5-di-alpha-cumylphehyl)-2H-benzotriazole, 5-chloro-2-(2-hydroxy-3-tert-butyl-5-methylphenyl)-2H-benzothiazole, 5-chloro-2-(2-hydroxy-3,5-di-tert-butylphenyl)-2H-benzotriazole, 2-(2-hydroxy-3,5-di-tert-amylphenyl)-2H-benzotriazole, 2-(2-hydroxy-3-alpha-cumyl-5-tert-octylphenyl)-2H-benzotriazole, 2-(3-tert-butyl-2-hydroxy-5-methylphenyl)-5-chloro-2Hbenzotriazole. Further preferred RUVA includes 2(-4,6-Diphenyl-1-3,5-triazin-2-yl)-5-hekyloxy-phenol. Exemplary UVAs include those available from Ciba Specialty Chemicals Corporation, Tarryton, N.Y. under the trade designation Tinuvin 1577, Tinuvin 900, and Tinuvin 777. In addition, the UVAs can be used in combination with hindered amine light stabilizers (HALS) and anti-oxidants. Exemplary HALS include those available from Ciba Specialty Chemicals Corporation, Tarryton, N.Y. under the trade designation Chimassorb 944 and Tinuvin 123. Exemplary anti-oxidants include Irganox 1010 and Ultranox 626, also available from Ciba Specialty Chemicals Corporation, Tarryton, N.Y.

In addition to adding UVA, HALS, and anti-oxidants to the UV protective layer, the UVA, HALS, and anti-oxidants can be added to the multi-layer optical layers, and the optional durable top coat layers.

In an alternative embodiment, the compliant UV protective layer is a multi-layer optical film that reflects wavelengths of light from about 350 to about 400 nm, and even more preferably from 300 nm to 400 nm. The polymers that make the multilayer optical film preferably do not absorb UV light in the 300 nm to 400 nm range. Non-limiting examples include PET/THV, PMMA/THV, PET/SPOX, PMMA/SPOX, sPS/THV, sPS/SPOX, modified polyolefin copolymers (EVA) with THV, TPU/THV, and TPU/SPOX. In a preferred embodiment, Dyneon THV 220 grade and 2030 grade, from Dyneon LLC, Oakdale, Minn. are employed with PMMA for multilayer UV mirrors reflecting 300-400 nm or with PET for multilayer mirrors reflecting 350-400 nm. In general, 100 to 1000 total layers of the polymer combinations are suitable for use with the present invention.

Other additives may be included in the UV protective layer. Small particle non-pigmentary zinc oxide and titanium oxide can also be used as blocking or scattering additives in the UV protective layer. For example, nano-scale particles can be dispersed in polymer or coating substrates to minimize UV radiation degradation. The nano-scale particles are transparent to visible light while either scattering or absorbing harmful UV radiation thereby reducing damage to thermoplastics. U.S. Pat. No. 5,504,134 describes attenuation of polymer substrate degradation due to ultraviolet radiation through the use of metal oxide particles in a size range of about 0.001 micrometer to about 0.20 micrometer in diameter, and more preferably from about 0.01 to about 0.15 micrometers in diameter. U.S. Pat. No. 5,876,688 teaches a method for producing micronized zinc oxide that are small enough to be transparent when incorporated as UV blocking and/or scatterring agents in paints, coatings, finishes, plastic articles, cosmetics and the like which are well suited for use in the present invention. These fine particles such as zinc oxide and titanium oxide with particle size ranged from 10-100 nm that can attenuate UV radiation are commercially available from Kobo Products, Inc. South Plainfield, N.J. Flame retardants may also be incorporated as an additive in the UV protective layer.

The thickness of the UV protective layer is dependent upon an optical density target at specific wavelengths as calculated by Beers Law. In a preferred embodiments, the UV protective layer has an optical density greater than 3.5 at 380 nm; greater than 1.7 at 390; and greater than 0.5 at 400 nm. Those of ordinary skill in the art recognize that the optical densities must remain fairly constant over the extended life of the article in order to provide the intended protective function.

The UV protective layer, and any optional additives, may be selected to achieve the desired protective functions such as UV protection, ease in cleaning, and durability in the solar concentrating mirror. Those of ordinary skill in the art recognize that there are multiple means for achieving the noted objectives of the UV protective layer. For example, additives that are very soluble in certain polymers may be added to the composition. Of particular importance, is the permanence of the additives in the polymer. The additives should not degrade or migrate out of the polymer. Additionally, the thickness of the layer may be varied to achieve desired protective results. For example, thicker UV protective layers would enable the same UV absorbance level with lower concentrations of UVA, and would provide more UVA permanence attributed to less driving force for UVA migration. One mechanism for detecting the change in physical characteristics is the use of the weathering cycle described in ASTM G155 and a D65 light source operated in the reflected mode. Under the noted test, and when the UV protective layer is applied to the article, the article should withstand an exposure of at least 18,700 kJ/m̂2 at 340 nm before the b* value obtained using the CIE L*a*b* space increases by 4 or less, or before the onset of significant cracking, peeling, delamination or haze.

### Tie Layer

An optional tie layer may be interposed between the multilayer optical film and the UV protective layer to assist in the adherence of the films and provide long term stability while the article of the present invention is exposed to outdoor elements. Non-limiting examples of tie layers include: SPOX, and CoPETs including modifications such as with functional groups sulfonic acids, PMMA/PVDF blends, modified olefins with functional comonomers such as maleic anhydride, acrylic acid, methacrylic acid or vinyl acetate. Additionally, UV or thermally curable acrylates, silicones, epoxies, siloxanes, urethane acrylates may be suitable as tie layers. The tie-layers may optionally contain UV absorbers as described above. The tie layers may optionally contain conventional plasticizers, tackifiers, or combinations thereof. The tie layer may be applied utilizing conventional film forming techniques.

### Optional Top Coat

The article may optionally include a durable top coat to assist in preventing the premature degradation of the solar concentrating mirror due to exposure to outdoor elements. The durable topcoat is generally abrasion and impact resistant and does not interfere with the primary function of reflecting a selected bandwidth of electromagnetic radiation. Durable top coat layers may include one or more of the following non-limiting examples, PMMA/PVDF blends, thermoplastic polyurethanes, curable polyurethanes, CoPET, cyclic olefin copolymers (COC's), fluoropolymers and their copolymers such as PVDF, ETFE, FEP, and THV, thermoplastic and curable acrylates, cross-linked acrylates, cross-linked urethane acrylates, cross-linked urethanes, curable or cross-linked polyepoxides, and SPOX. Strippable polypropylene copolymer skins may also be employed. Alternatively, silane silica sol copolymer hard coating can be applied as a durable top coat to improve scratch resistance. The durable top coat may contain UV absorbers, HALS, and anti-oxidants as described above.

The durable top coat provides mechanical durability to the article. Some mechanisms for measuring mechanical durability may be either impact or abrasion resistance. Taber abrasion is one test to determine a film's resistance to abrasion, and resistance to abrasion is defined as the ability of a material to withstand mechanical action such as rubbing scrapping, or erosion. According to the ASTM D1044 test method, a 500-gram load is placed on top of CS-10 abrader wheel and allowed to spin for 50 revolutions on a 4 sq. inch test specimen. The reflectivity of the sample before and after the Taber abrasion test is measured, and results are expressed by changes in % reflectivity. For the purpose of this invention, change in % reflectivity is expected to be less than 20%, preferred to be less than 10% and particularly more preferred to be less than 5%.

Other suitable tests for mechanical durability include break elongation, pencil hardness, sand blast test, and sand shaking abrasion. UVA's and appropriate UV stabilizers described above can be added into the top coat for stabilizing the coating as well as for protection of the substrates. The substrates coated with such a durable hard coat are thermoformable before being fully cured at an elevated temperature, and a durable hard coat can then be formed by a post curing at 80° C. for 15-30 minutes. In addition, siloxane components used as a durable top coat are hydrophobic in nature and can provide an easy clean surface function to the articles disclosed in this invention

Due to the outdoor application, weathering is also an important characteristic of the solar concentrating mirror. Accelerated weathering studies are one option for qualifying the performance of the article. Accelerated weathering studies are generally performed on films using techniques similar to those described in ASTM G-155, “Standard practice for exposing non-metallic materials in accelerated test devices that use laboratory light sources”. The noted ASTM technique is considered as a sound predictor of outdoor durability, i.e., ranking materials performance correctly.

In an alternative embodiment, a reverse construction may be employed on a side of the multilayer optical film opposite the required UV protective layer. The alternative construction can provide additional functional features for specific applications of the article. For example, it may be desirable to provide an additional UV protective layer on the multilayer optical film in order to provide backside protection from UV radiation. Other potential embodiments can include carbon black or an IR absorbing layer on the side opposite the direct exposure to the sun. Another alternative embodiment may include an antireflective coating on the backside to prevent backside IR reflection. Tie layers, such as those previously disclosed, can be used in providing the alternative embodiments.

The resulting physical characteristics of the film provide enhanced properties when applied as a solar concentrating mirror for focusing specific bandwidths of electromagnetic radiation onto a solar cell. The multilayer optical film, in combination with a UV protective film of a selected thickness, may be designed to reflect a desired bandwidth of electromagnetic radiation while transmitting undesirable electromagnetic radiation. The unique capability to select multilayer optical films to match specific solar cells, while reducing radiation adverse to the solar cell, significantly enhances the operational efficiency of the solar cell. Some embodiments exhibit a reflectivity of 98% or greater of light corresponding to the absorption bandwidth of the selected solar cell.

The solar concentrating mirror may be positioned in close proximity to the solar cell to enable the desired level of reflection onto the solar cell. The article may be a stand alone application or alternatively may be applied onto a substrate to provide additional rigidity, or dimensional stability. Suitable substrates include, for example, glass sheet, polymeric sheets, and polymer fiber composites including glass fiber composites. An optional tie layer, such as those previously described, may be employed in bonding the article to the substrate. In another alternative embodiment, the article may be thermoformed into shapes or dimensions conventionally used for solar concentrators. Additionally, the substrate may have corrugation or ribs to improve its dimensional stability. Thermoforming is generally described in U.S. Pat. No. 6,788,463 herein incorporated by reference in its entirety.

### Solar Cells

Suitable solar cells include those that have been developed with a variety of materials each having a unique absorption spectra that converts solar energy into electricity. Each type of semiconductor material will have a characteristic band gap energy which causes it to absorb light most efficiently at certain wavelengths of light, or more precisely, to absorb electromagnetic radiation over a portion of the solar spectrum. Examples of materials used to make solar cells and their solar light absorption band-edge wavelengths include, but are not limited to: crystalline silicon single junction (about 400 nm to about 1150 nm), amorphous silicon single junction (about 300 nm to about 720 nm), ribbon silicon (about 350 nm to about 1150 nm), CIGS (Copper Indium Gallium Selenide) (about 350 m to about 1100 nm), CdTe (about 400 nm to about 895 nm), GaAs multi-junction (about 350 nm to about 1750 nm). The shorter wavelength left absorption band edge of these semiconductor materials is typically between 300 nm and 400 nm. One skilled in the art understands that new materials are being developed for more efficient solar cells having their own unique longer wavelength absorption band-edge and the multi-layer reflective film would have a corresponding reflective band-edge.

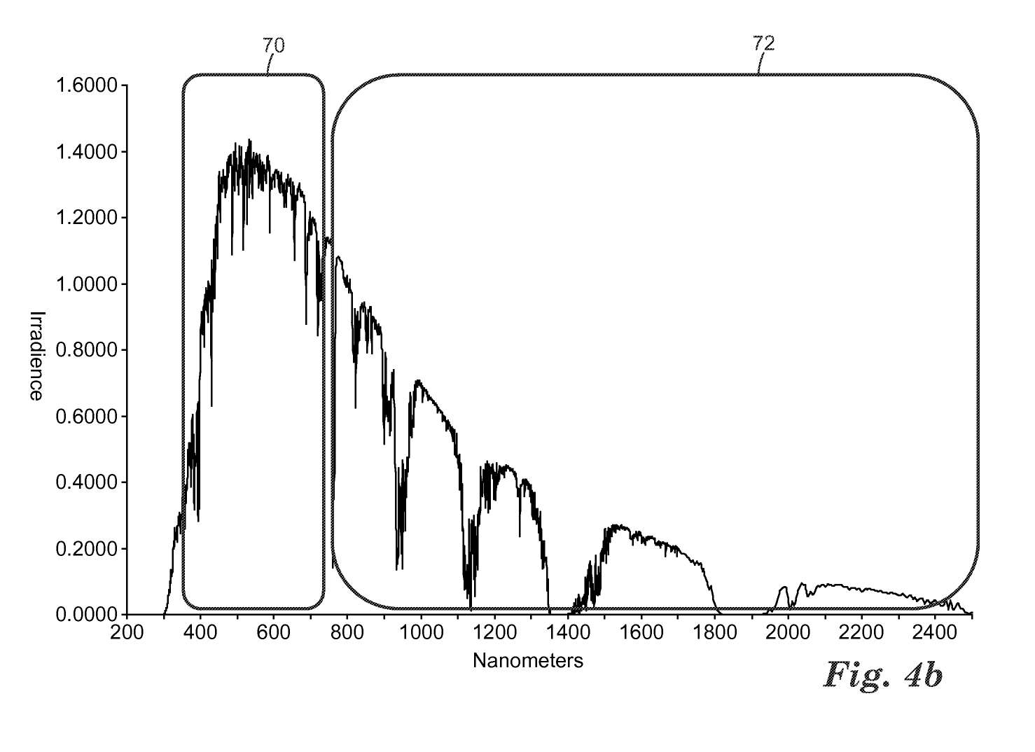

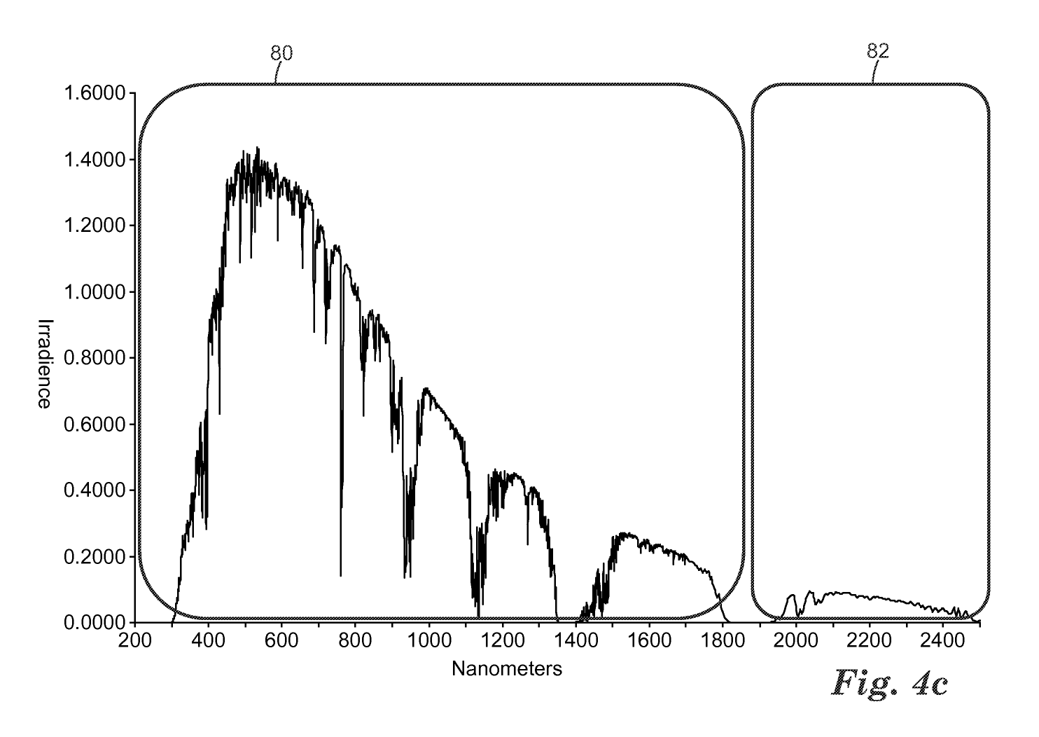

FIGS. 4a, 4b, and 4c depict potential applications of the article of the present invention in combination with specific solar cells. FIG. 4a is a graph of the solar spectrum versus absorption for a crystalline silicon single junction solar cell. FIG. 4a illustrates an operating window 60 that corresponds with the reflection of visible and near infrared electromagnetic radiation up to about 1150 nm. The far infrared region 62, greater than about 1150 nm, is not reflected. Another example using an amorphous silicon single junction is depicted in FIG. 4b. In FIG. 4b, the operating window 70 of the article of the present invention corresponds with the longer wavelength (infrared) absorption band-edge of an amorphous silicon single junction solar cell. The infrared region 72 is not reflected by the article of the present invention. FIG. 4c, illustrates the application of a concentrating mirror with an GaAs multi-junction solar cell having a longer wavelength (infrared) absorption band-edge of about 1750 nm. In FIG. 4c, the operating window 80 corresponds to the reflected electromagnetic radiation by the article of the present invention. The infrared radiation 82 is not reflected by the concentrating mirror.

As illustrated in FIGS. 4a, 4b, and 4c, the concentrating mirror, when placed in close proximity to a selected solar cell, is utilized to reflect at least a major portion of the average light across the range of wavelengths corresponding with the absorption bandwidth of the solar cell onto the solar cell. The concentrating mirror does not reflect onto the solar cell a major portion of light outside the absorption bandwidth of the solar cell. The major portion of the average light across the range of wavelengths that corresponds with the absorption bandwidth of a selected solar cell reflected by the article represents a value selected from greater than 50%, preferably greater than 70%, preferably greater than 80%, more preferably greater than 90%, or even more preferably greater than 95%. Electromagnetic radiation outside the absorption bandwidth of the solar cell is transmitted or absorbed by the concentrating mirror. The light across the range of wavelengths that corresponds with the absorption bandwidth of the solar cell is concentrated onto the solar cell by an amount greater than one, preferably greater than 50. A concentrating mirror in combination with a silicon single junction cell will reflect light from about 400 nm to about 1200 nm with at least a major portion of light greater than 1200 nm not reflected. A concentrating mirror in combination with a multi-junction cell will reflect light from about 350 nm to about 1750 nm with at least a major portion of light greater than 1750 nm not reflected.

The concentrating mirrors of the present invention enhance the efficiency of solar cells due to (i) a significant reduction of a non-selected bandwidth that in effect minimizes overheating of solar cell; (ii) an increased power output obtained with polymeric mirrors that result in lower costs per produced energy ($/Watt); and (iii) increased durability due to UV protection and abrasion resistance.

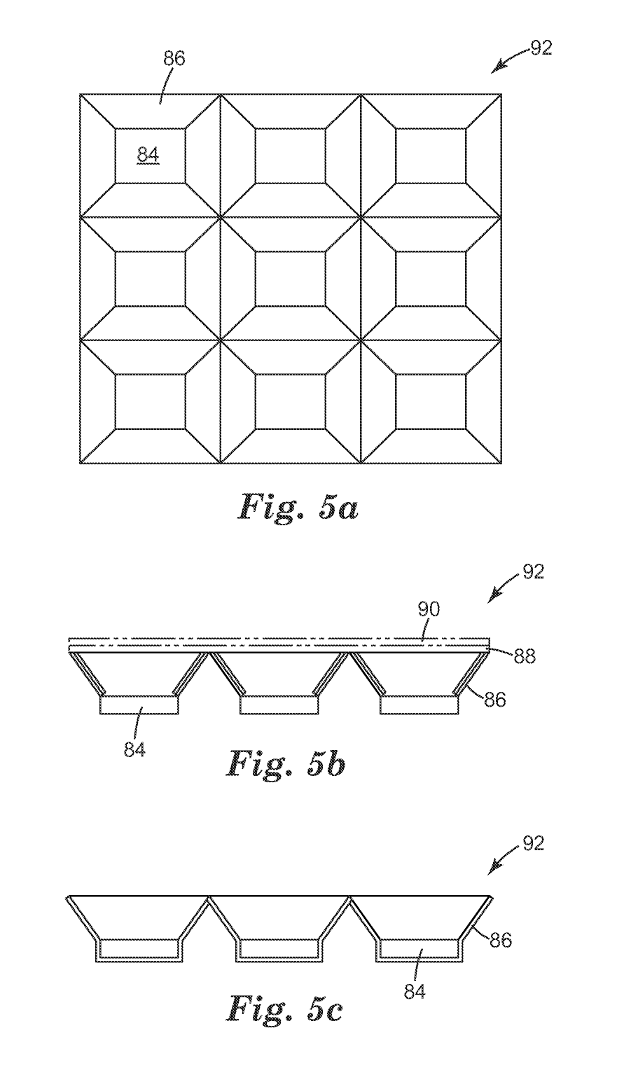

FIGS. 5a, 5b and 5c illustrate an application of the concentrating mirror and an array of solar cells. In FIG. 5a, solar cells 84 are placed into an array 92 with multiple concentrating mirrors 86 positioned in close proximity to the solar cells to reflect to reflect onto the solar cell at least a major portion of the average light across the range of wavelengths corresponding with the absorption bandwidth of the solar cell. Light outside of the desired bandwidth is not reflected by the concentrating mirror. In FIG. 5b, the array of solar cells 84 and the concentrating mirror 86 are shown in a schematic cross sectional view with an optional ultraviolet mirror 88 and an optional infrared mirror 90. FIG. 5c depicts an alternative embodiment indicating that the concentrating mirror 86 is thermoformed around the solar cells 84. In this embodiment, the concentrating mirror 86 reflects from the sides and back of the solar cell 84 to further enhance the efficiency of the system.

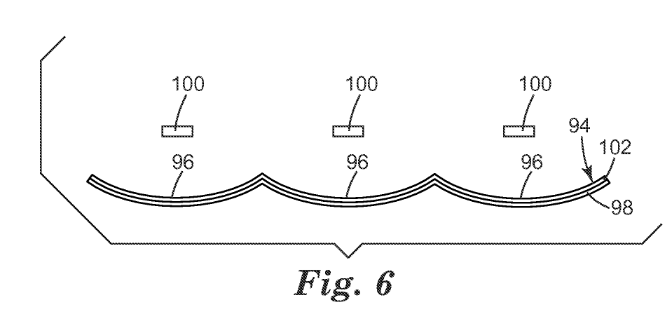

Those of ordinary skill in the art recognize that the application of the solar concentrating mirror of the present invention could occur in various arrangements and arrays in combination with solar cells. FIG. 6 is a solar concentrating mirror 94 comprising an array of multiple curved surface mirrors 96 comprising continuous multilayer mirror 98 laminated to continuous UV protective layer 102 that concentrate solar light onto solar cells 100.

The solar concentrating mirror, in combination with a solar cell, may be further applied with other conventional solar collection devices to further enhance the application of the solar concentrating mirror. For example, thermal transfer devices may be applied to either collect energy from the solar cell or dissipate heat from the solar cell. Conventional thermal heat sinks include thermally conductive materials that include ribs, pins or fins to enhance the surface area for heat transfer. The thermally conductive materials include metals or polymers modified with fillers to improve the thermal conductivity of the polymer. Additionally, conventional heat transfer fluids, such as water, oils or fluoroinert heat transfer fluids may be employed as thermal transfer devices. Alternatively, an array of solar cells, in combination with the concentrating mirror, can be placed on conventional celestial tracking devices.

### EXAMPLES

### Comparative Example 1

A multilayer optical film was made with first optical layers created from polyethylenenaphthalate (PEN) made by the 3M Company, St. Paul, Minn. and second optical layers created from polymethylmethacrylate (PMMA) from Arkema Inc. Philadelphia, Pa. and sold under the trade designation as VO44. PEN and PMMA were coextruded thru a multilayer polymer melt manifold to create a multilayer melt stream having 530 alternating first and second optical layers. In addition to the first and second optical layers, a pair of non-optical layers also comprised of PEN were coextruded as protective skin layers on either side of the optical layer stack. This multilayer coextruded melt stream was cast onto a chilled roll at 22 meters per minute creating a multilayer cast web approximately 1075 microns (43 mils) thick. The multilayer cast web was then heated in a tenter oven at 145 C for 10 seconds prior to being biaxially oriented to a draw ratio of 3.8×3.8. The oriented multilayer film was further heated to 225° C. for 10 seconds to increase crystallinity of the PEN layers. Reflectivity of this multilayer visible mirror film was measured with a Lambda 950 spectrophotometer to have an average reflectivity of 98.5% over a bandwidth of 390-850 nm. After 3000 hrs exposure to Xenon arc lamp weatherometer according to ASTM G155-05a, a change in b* of 5 units was measured with a Lambda 950 spectrophotometer.

### Example 1

A multilayer optical film was made with birefringent layers created from PEN and second polymer layers created from PMMA. PEN and PMMA were coextruded thru a multilayer polymer melt manifold to create a multilayer melt stream having 275 alternating birefringent layers and second polymer layers. In addition, a pair of non-optical layers also comprised of PEN were coextruded as protective skin layers on either side of the optical layer stack. This multilayer coextruded melt stream was cast onto a chilled roll at 22 meters per minute creating a multilayer cast web approximately 725 microns (29 mils) thick. The multilayer cast web was then heated in a tenter oven at 145° C. for 10 seconds prior to being biaxially oriented to a draw ratio of 3.8×3.8. The oriented multilayer film was further heated to 225° C. for 10 seconds to increase crystallinity of the PEN layers. Reflectivity of this multilayer visible mirror film was measured with a Lambda 950 spectrophotometer resulting in an average reflectivity of 98.5% over a bandwidth of 400-1000 nm. PMMA, (VO44) from Arkema Inc. Philadelphia, Pa., was extrusion compounded with 5 wt % Tinuvin 1577 and 0.15 wt % Chimassorb 944, both from CIBA Specialty Chemicals Corp, Tarryton, N.Y., and an adhesive tie-layer sold by E.I. duPont de Nemours & Co., Inc., Wilmington, Del., under the trade designation Bynel E418, were coextrusion coated onto a multilayer mirror film made as described above and simultaneously directed into a nip under a pressure of 893 kg/m (50 pounds per lineal inch) against a casting tool having a mirror finish surface at a temperature of 90° F., at a casting line speed of 0.38 m/sec (75 feet per minute). The coextrusion coated layers have a total thickness of 254 um (10 mil) with skin tie-layer thickness ratio of 20:1. The same materials were coextrusion coated onto the opposing surface of the multilayer visible mirror film. The UV absorption band edge of this extrusion coat has 50% transmission at 410 nm and absorbance of 3.45 at 380 nm. Change in b* was measured to be less than 1.0 after 3000 hrs exposure to Xenon arc lamp weatherometer according to ASTM G155-05a.

### Example 2

A multilayer reflective mirror is made with birefringent layers created from PEN and second polymer layers created from polyoxamide silicone (SPOX) available from 3M Company, St. Paul, Minn. PEN and SPOX layers are coextruded thru a multilayer polymer melt manifold to create a multilayer melt stream having 550 alternating first and second optical layers. In addition to the birefringent layers and second polymer layers, a pair of non-optical layers also comprised of PEN are coextruded as protective skin layers on either side of the optical layer stack. This multilayer coextruded melt stream is cast onto a chilled roll at 22 meters per minute creating a multilayer cast web approximately 1400 microns (56 mils) thick. The multilayer cast web is then heated in a tenter oven at 145° C. for 10 seconds prior to being biaxially oriented to a draw ratio of 3.8×3.8. The oriented multilayer film is further heated to 225° C. for 10 seconds to increase crystallinity of the PEN layers. Reflectivity of this multilayer visible mirror film is measured with a Lambda 950 spectrophotometer and results in an average reflectivity of 98.9% over a bandwidth of 390-1750 nm. PMMA-UVA/HALS from Example 1 is coextrusion coated onto a multilayer mirror film made as described above and simultaneously directed into a nip under a pressure of 893 kg/m (50 pounds per lineal inch) against a casting tool having a mirror finish surface at a temperature of 90° F., at a casting line speed of 0.38 m/sec (75 feet per minute). The coextrusion coated layers will have a total thickness of 254 um (10 mil) with skin tie-layer thickness ratio of 20:1. The same materials are coextrusion coated onto the opposing surface of the multilayer visible mirror film. The UV absorption band edge of this extrusion coat has a 50% transmission at 410 nm and absorbance of 3.45 at 380 nm. Change in b* is expected to be less than 2.0 after 3000 hrs exposure to Xenon arc lamp weatherometer according to ASTM G155-05a.

### Example 3

A multilayer reflective mirror is made with birefringent layers created from PET and second polymer layers created from SPOX, both available from the 3M Company. PET and SPOX are coextruded thru a multilayer polymer melt manifold to create a multilayer melt stream having 550 alternating birefringent layers and second polymer layers. In addition, a pair of non-optical layers also comprised of PET are coextruded as protective skin layers on either side of the optical layer stack. This multilayer coextruded melt stream is cast onto a chilled roll at 22 meters per minute creating a multilayer cast web approximately 1400 microns (56 mils) thick. The multilayer cast web is then be heated in a tenter oven at 95° C. for 10 seconds prior to being biaxially oriented to a draw ratio of 3.8×3.8. The oriented multilayer film is further heated to 225° C. for 10 seconds to increase crystallinity of the PET layers. Reflectivity of this multilayer visible mirror film is measured with a Lambda 950 spectrophotometer resulting in an average reflectivity of 98.4% over a bandwidth of 390-1200 nm. A PMMA-UVA/HALS composition from Example 1, and an adhesive tie-layer from Example 1 are coextrusion coated onto a multilayer mirror film made as described above and simultaneously directed into a nip under a pressure of 893 kg/m (50 pounds per lineal inch) against a casting tool having a mirror finish surface at a temperature of 90° F., at a casting line speed of 0.38 m/sec (75 feet per minute). The coextrusion coated layers will have a total thickness of 254 um (10 mil) with skin tie-layer thickness ratio of 20:1. The same materials are coextrusion coated onto the opposing surface of the multilayer visible mirror film. The UV absorption band edge of this extrusion coat has 50% transmission at 410 nm and absorbance of 3.45 at 380 nm. No change in b* is expected after 3000 hrs exposure to Xenon arc lamp weatherometer according to ASTM G155.

### Example 4

A multilayer reflective mirror is made with birefringent layers created from PEN and second polymer layers created from a fluoropolymer available as THV2030 from Dyneon LLC, Oakdale, Minn. PEN and THV are coextruded thru a multilayer polymer melt manifold to create a multilayer melt stream having 550 alternating first birefringent and second polymer layers. In addition to the birefringent layers and second polymer layers, a pair of non-optical layers also comprised of PEN are coextruded as protective skin layers on either side of the optical layer stack. This multilayer coextruded melt stream is cast onto a chilled roll at 22 meters per minute creating a multilayer cast web approximately 1400 microns (56 mils) thick. The multilayer cast web is then be heated in a tenter oven at 145° C. for 10 seconds prior to being biaxially oriented to a draw ratio of 3.8×3.8. The oriented multilayer film is further heated to 225° C. for 10 seconds to increase crystallinity of the PEN layers. Reflectivity of this multilayer visible mirror film is measured with a Lambda 950 spectrophotometer resulting in an average reflectivity of 99.5% over a bandwidth of 390-1750 nm. PMMA-UVA/HALS from Example 1, and an adhesive tie-layer from Example 1 are coextrusion coated onto a multilayer mirror film made as described above and simultaneously directed into a nip under a pressure of 893 kg/m (50 pounds per lineal inch) against a casting tool having a mirror finish surface at a temperature of 90° F., at a casting line speed of 0.38 m/sec (75 feet per minute). The coextrusion coated layers will have a total thickness of 254 um (10 mil) with skin tie-layer thickness ratio of 20:1. The same materials are coextrusion coated onto the opposing surface of the multilayer visible mirror film. The UV absorption band edge of this extrusion coat will have 50% transmission at 410 nm and absorbance of 3.45 at 380 nm. The expected change in b* is measured to be less than 2.0 after 3000 hrs exposure to Xenon arc lamp weatherometer according to ASTM G155.

### Example 5

A multilayer reflective mirror is made with birefringent polymer layers created from PET and second polymer layers created from THV2030 from Dyneon LLC. PET and THV2030 are coextruded thru a multilayer polymer melt manifold to create a multilayer melt stream having 550 alternating first and second polymer layers. In addition to the birefringent layers and second polymer layers, a pair of non-optical layers also comprised of PET are coextruded as protective skin layers on either side of the optical layer stack. This multilayer coextruded melt stream is cast onto a chilled roll at 22 meters per minute creating a multilayer cast web approximately 1400 microns (56 mils) thick. The multilayer cast web is then be heated in a tenter oven at 95° C. for 10 seconds prior to being biaxially oriented to a draw ratio of 3.8×3.8. The oriented multilayer film is further heated to 225° C. for 10 seconds to increase crystallinity of the PET layers. Reflectivity of this multilayer visible mirror film is measured with a Lambda 950 spectrophotometer resulting in an average reflectivity of 99% over a bandwidth of 390-1200 nm. PMMA-UVA/HALS from Example 1, and an adhesive tie-layer from Example 1 is coextrusion coated onto a multilayer mirror film made as described above and simultaneously directed into a nip under a pressure of 893 kg/m (50 pounds per lineal inch) against a casting tool having a mirror finish surface at a temperature of 90° F., at a casting line speed of 0.38 m/sec (75 feet per minute). The coextrusion coated layers will have a total thickness of 254 um (10 mil) with skin tie-layer thickness ratio of 20:1. The same materials are coextrusion coated onto the opposing surface of the multilayer visible mirror film. The UV absorption band edge of this extrusion coat will have 50% transmission at 410 nm and absorbance of 3.45 at 380 nm. No change in b* is expected after 3000 hrs exposure to Xenon arc lamp weatherometer according to ASTM G155.

### Example 6

An article resulting from any of the Examples 2-5 are laminated to or coextruded with a multilayer UV mirror made with UV transparent polymers such as PMMA and THV. This multilayer UV reflective mirror is made with first optical layers created from PMMA and second polymer layers created from THV2030. PMMA and THV2030 are coextruded thru a multilayer polymer melt manifold to create a multilayer melt stream having 150 alternating birefringent layer and second polymer layers. Additionally, a pair of non-optical layers also comprised of PMMA are coextruded as protective skin layers on either side of the optical layer stack. These PMMA skins layers are extrusion compounded with 2 wt % Tinuvin 405. This multilayer coextruded melt stream are cast onto a chilled roll at 22 meters per minute creating a multilayer cast web approximately 300 microns (12 mils) thick. The multilayer cast web is then heated in a tenter oven at 135° C. for 10 seconds prior to being biaxially oriented to a draw ratio of 3.8×3.8. Reflectivity of this multilayer UV mirror film is measured with a Lambda 950 spectrophotometer resulting in an average reflectivity of 95% over a bandwidth of 350-420 nm.

### Example 7

A durable mirror as described in Example 2-6 is additionally coated with a thermally cured siloxane, such as Perma-New 6000 from California Hardcoat Co., Chula Vista, Calif., (a silica-filled methylpolysiloxane polymer) is applied to acrylic substrates by a Meyer rod with a coating thickness about 3.5-6.5 microns. The coating is first air-dried at room temperature for few minutes, and then further cured in a conventional oven for 15-30 minutes at 80° C. A resulting thermally cured coated sample is tested by sand shaking abrasion. After the sample is abraded by sand shaking for 60 minutes with silica sands, haze of the sample is measured. Expected results will indicate a haze as low as less then 1%. This form of durable top coat will have better abrasion/scratch resistance than PMMA as measured with a Taber abrasion test.

### Example 8

A durable solar concentrating mirror as described in Example 1 was preheated at 400° F. for 35 seconds and then vacuum thermoformed to a 4″ diameter parabolic mold having a 6″ radius of curvature. The thermoformed durable mirror was rigid and maintained the thermoformed shape at temperatures of 85° C. The parabolic multilayer mirror is capable of concentrating greater than 100 times the sun's radiation onto a high efficiency triple junction GaAs photovoltaic cell.

### Example 9

Durable mirrors as described in Example 1 were attached to a Sharp 80W multicrystalline silicon photovoltaic module comparable to that depicted in FIG. 2. The durable mirrors had the same dimensions (same surface area) as the solar cell, and were attached at a 55 degree angle from the surface of the solar cell module. When faced normal to the Sun, the solar cell produced 65% more power than without the durable mirrors attached, and the temperature increase measured on the backside of the solar cell was less than 10° C. higher than without the durable mirror solar concentrators. With the Sun at a 30 degree angle from the surface of the solar cell, and one durable mirror also at a 30 degree angle from the surface of the solar cell, and the other durable mirror adjusted parallel to the surface of the solar cell, the solar cell produced 95% more power than without the durable mirrors attached, and the temperature increased measured on the backside of the solar cell was less than 15° C. higher than without the durable mirror concentrators.

What is claimed is:

1. An article comprising:
(a) multilayer optical film having an optical stack comprising a plurality of alternating layers, the alternating layers having at least one birefringent polymer layer and at least one second polymer layer;
(b) and a compliant UV protective layer applied onto a surface of the multilayer optical film, wherein the article reflects at least a major portion of the average light across the range of wavelengths that corresponds with the absorption bandwidth of a selected solar cell and either transmits or absorbs a major portion of light outside the absorption bandwidth of the selected solar cell.

2. An article according to claim 1, further comprising layers selected from (i) a durable top coat applied to an opposing surface of the compliant UV protective layer, (ii) a tie layer interposed between the multilayer optical film and the compliant UV protective layer, or (iii) combinations thereof.

3. An article according to claim 1, wherein the at least a major portion of the average light across the range of wavelengths that corresponds with the absorption bandwidth of a selected solar cell reflected by the article represents a value greater than the value selected from 50%, 70%, 80%, 90% or 95%.

4. An article according to claim 1, wherein the compliant UV protective layer either reflects UV light, absorbs UV light, scatters UV light, or a combination thereof.

5. An article according to claim 1, wherein the compliant UV protective layer is a multi-layer UV reflective mirror.

6. An article according to claim 1, wherein the compliant UV protective layer, any one of the alternating layers, or combinations thereof includes one or more compounds selected from ultra violet absorbers, hindered amine light stabilizers, anti-oxidants, optical brighteners, fluorescing molecules, nano-particles, flame retardants and combinations thereof.

7. An article according to claim 1, wherein the compliant UV protective layer has an optical density greater than 4 at 380 nm.

8. An article according to claim 1, wherein the article is thermoformable.

9. An article according to claim 1, further comprising an additional compliant UV protective layer applied to an opposing side of the multilayer optical film opposite component (b).

10. An article according to claim 1, wherein the article can withstand an exposure of at least 18,700 kJ/m² at 340 nm before the b* value obtained using the CIE L*a*b* space increases by a value no greater than 5, or before the onset of significant cracking, peeling, delamination, or haze, when evaluated using the weathering cycle described in ASTM G155-05a and a D65 light source operated in the reflected mode.

11. An article according to claim 1, wherein the article is applied to a substrate selected from a polymeric sheet, a glass sheet, or polymer fiber composites, and wherein an optional ultra-violet absorber is included in the substrate.

12. An article according to claim 1, wherein the multilayer optical film is selected from the following high and low refractive index polymer combinations PET/THV, PET/SPOX, PEN/THV, PEN/SPOX, PEN/PMMA, PET/CoPMMA, PEN/CoPMMA, CoPEN/PMMA, CoPEN/SPOX, CoPEN/THV, CoPEN/Fluoroelastomer sPS/SPOX, sPS/THV, or sPS/Fluoroelastomer.

13. An article according to claim 1, wherein the article exhibits a reflectivity of 98% or greater of light corresponding to the absorption bandwidth of the selected solar cell.

14. An article comprising:
(a) one or more solar cells having an absorption bandwidth;
(b) one or more compliant films positioned in proximity to the solar cell, wherein the film is a combination of (i) multilayer optical film having an optical stack having a plurality of alternating layers, the alternating layers having at least one birefringent polymer and at least one second polymer; and (ii) and a UV protective layer applied onto a surface of the multilayer optical film, wherein the compliant film reflects at least a major portion of the average light across the range of wavelengths that corresponds with the absorption conversion bandwidth of the solar cell onto the solar cell and does not reflect onto the solar cell a major portion of light outside the absorption bandwidth of the solar cell.

15. An article according to claim 14, wherein the solar cell is selected from (i) a crystalline silicon single junction cell and the compliant film reflects light from about 400 to about 1150 nm with at least a major portion of light greater than 1150 nm not reflected, (ii) a multi-junction GaAs cell and the compliant film reflects light from about 350 nm to about 1750 nm with at least a major portion of light greater than 1750 nm not reflected, (iii) amorphous silicon single junction cell and the compliant film reflects light from about 300 to about 720 nm with at least a major portion of light greater than 720 nm not reflected, (iv) a ribbon silicon cell and the compliant film reflects light from about 400 to about 1150 nm with at least a major portion of light greater than 1150 nm not reflected, (v) a copper indium gallium selenide cell and the compliant film reflects light from about 350 to about 1100 nm with at least a major portion of light greater than 1100 nm not reflected, or (vi) cadmium telluride cell and the compliant film reflects light from about 400 to about 895 nm with at least a major portion of light greater than 895 nm not reflected.

16. An article according to claim 14, further comprising a thermal transfer device.

17. An article according to claim 14, wherein the light across the range of wavelengths that corresponds with the absorption bandwidth of the solar cell is concentrated onto the solar cell by an amount selected from greater than one, greater than 50, or greater than 100.

18. An article according to claim 14, further comprising an antireflective coating or a black absorbing layer on the multilayer optical film opposite the UV protective layer to prevent back side infrared reflection.

19. An article according to claim 14, wherein the compliant film is formed in a parabolic or curved shape and the solar cell is positioned above the compliant film.

20. An article according to claim 14, wherein the compliant film is thermoformed.

21. An article according to claim 14, wherein the compliant film is thermoformed and encompasses the solar cell such that light reflects onto more than one side of the solar cell.

22. An article according to claim 14, wherein the at least a major portion of the average light across the range of wavelengths that corresponds with the absorption bandwidth of a selected solar cell reflected by the article represents a value selected from greater than 50%, 70%, 80%, 90% or greater than 95%.

23. A solar collection device comprising the article of claim 1 formed into multiple reflective surfaces to concentrate light onto one or more solar cells.

24. A solar collection device according to claim 23, wherein the array encompasses one or more celestial tracker mechanisms.

25. A solar collection device according to claim 14, wherein the array encompasses one or more celestial tracker mechanisms.

26. A solar collection device according to claim 14, further comprising at least one infrared mirror, at least one UV mirror, or combinations thereof.

27. A method comprising positioning a compliant film in proximity to a solar cell wherein the film is a combination of (i) multilayer optical film having an optical stack having a plurality of alternating layers, the alternating layers having at least one birefringent polymer and at least one second polymer; and (ii) and a UV protective layer applied onto a surface of the multilayer optical film, wherein the compliant film reflects at least a major portion of the average light across the range of wavelengths that corresponds with the absorption bandwidth of the solar cell onto the solar cell and does not reflect onto the solar cell a major portion of light outside the absorption bandwidth of the solar cell.
